(19) United States
(12) Patent Application Publication
(10) Pub. No.: US 2026/0305421 A1
(43) Pub. Date: Oct. 1, 2026

(54) SEMICONDUCTOR DEVICE AND METHOD OF MANUFACTURING SEMICONDUCTOR DEVICE

(71) Applicant: MITSUBISHI ELECTRIC CORPORATION, Tokyo (JP)

(72) Inventors: Atsushi MAEDA, Tokyo (JP); Yuji IMOTO, Fukuoka (JP)

(73) Assignee: MITSUBISHI ELECTRIC CORPORATION, Tokyo (JP)

(21) Appl. No.: 19/489,083

(22) PCT Filed: Sep. 1, 2023
(86) PCT No.: PCT/JP2023/032084

§ 371 Date: Dec. 1, 2025

(51) Int. Cl. H10W 70/685; H10W 40/22; H10W 70/65

(52) U.S. Cl. CPC H10W 70/685; H10W 40/226; H10W 70/65

(57) ABSTRACT

An object is to provide a semiconductor device reducing a warpage after a power module substrate and a cooling fin are bonded. A first circuit pattern is attached to the cooling fin. An insulating substrate is provided above the first circuit pattern. A second circuit pattern is provided above the insulating substrate. A third circuit pattern is provided above the second circuit pattern. A plurality of intermediate members are provided between a cooling fin and the first circuit pattern, between the first circuit pattern and the insulating substrate, between the insulating substrate and the second circuit pattern, and between the second circuit pattern and the third circuit pattern, respectively. A thickness of the first circuit pattern is smaller than a thickness of at least one of the second circuit pattern and the third circuit pattern.

### TECHNICAL FIELD

The present disclosure relates to a semiconductor device and a method of manufacturing the semiconductor device.

### BACKGROUND ART

A power module substrate to which a power semiconductor element is mounted is attached to a cooling fin for cooling the power semiconductor element. Patent Document 1 discloses a power module substrate provided with a heatsink.

### PRIOR ART DOCUMENTS

### Patent Document(s)

Patent Document 1: Japanese Patent Application Laid-Open No. 2013-98423

### SUMMARY

### Problem to Be Solved by the Invention

A power module substrate to which a power semiconductor element is mounted has a multilayer structure made up of an insulating substrate and a circuit pattern. Thus, a warpage may occur when the power module substrate is bonded to a cooling fin.

In order to solve the above problems, an object of the present disclosure is to provide a semiconductor device reducing a warpage after a power module substrate and a cooling fin are bonded.

### Means to Solve the Problem

A semiconductor device according to the present disclosure includes a cooling fin, a first circuit pattern, an insulating substrate, a second circuit pattern, a third circuit pattern, and a plurality of intermediate members. The first circuit pattern is attached to the cooling fin. The insulating substrate is provided above the first circuit pattern. The second circuit pattern is provided above the insulating substrate. The third circuit pattern is provided above the second circuit pattern. The plurality of intermediate members are provided between the cooling fin and the first circuit pattern, between the first circuit pattern and the insulating substrate, between the insulating substrate and the second circuit pattern, and between the second circuit pattern and the third circuit pattern, respectively. A thickness of the first circuit pattern is smaller than a thickness of at least one of the second circuit pattern and the third circuit pattern.

### Effects of the Invention

According to the present disclosure, provided is a semiconductor device reducing a warpage after a power module substrate and a cooling fin are bonded.

These and other objects, features, aspects and advantages of the present disclosure will become more apparent from the following detailed description of the present disclosure when taken in conjunction with the accompanying diagrams.

### BRIEF DESCRIPTION OF DRAWINGS

FIG. 1 is a cross-sectional view illustrating a configuration of a semiconductor device according to an embodiment 1.

FIG. 2 is a cross-sectional view illustrating a configuration of a member included in the semiconductor device.

FIG. 3 is a flow chart illustrating a method of manufacturing the semiconductor device according to the embodiment 1.

FIG. 4 is a cross-sectional view illustrating a configuration of a semiconductor device according to a modification example 1 of the embodiment 1.

FIG. 5 is a cross-sectional view illustrating a configuration of a member included in the semiconductor device.

FIG. 6 is a cross-sectional view illustrating a configuration of a semiconductor device according to a modification example 2 of the embodiment 1.

FIG. 7 is a cross-sectional view illustrating a configuration of a member included in the semiconductor device.

FIG. 8 is a cross-sectional view illustrating a configuration of a semiconductor device according to an embodiment 2.

FIG. 9 is a cross-sectional view illustrating a configuration of a member included in the semiconductor device.

FIG. 10 is a cross-sectional view illustrating a configuration of a semiconductor device according to an embodiment 3.

FIG. 11 is a cross-sectional view illustrating a configuration of a member included in the semiconductor device.

### DESCRIPTION OF EMBODIMENT(S)

### Embodiment 1

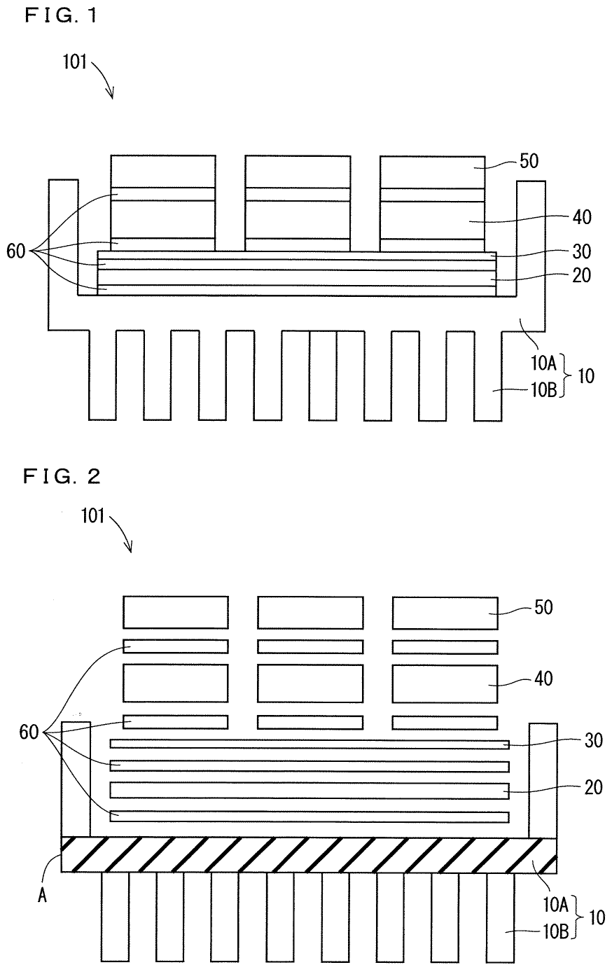

FIG. 1 is a cross-sectional view illustrating a configuration of a semiconductor device 101 according to an embodiment 1. FIG. 2 is a cross-sectional view illustrating a configuration of a member included in the semiconductor device 101. The semiconductor device 101 includes a cooling fin 10, a first circuit pattern 20, an insulating substrate 30, a second circuit pattern 40, a third circuit pattern 50, a plurality of intermediate members 60, and a semiconductor element (not shown). A structure including the first circuit pattern 20, the insulating substrate 30, the second circuit pattern 40, the third circuit pattern 50, and the plurality of intermediate members 60 is referred to as a power module substrate hereinafter.

The cooling fin 10 includes a plate part 10A and a fin part 10B. The fin part 10B is provided to a lower surface of the plate part 10A. The plate part 10A includes an attachment surface on an upper surface. The cooling fin 10 has a function of transmitting heat generated in an electrical component such as the semiconductor element to an outer part. The cooling fin 10 is formed of metal such as copper or aluminum, for example. The cooling fin 10 is also referred to as a heatsink or a heat radiator.

The first circuit pattern 20 is attached to an attachment surface of the cooling fin 10 via an intermediate member 60. The first circuit pattern 20 is formed of Al—Mg—Si alloy, for example. The first circuit pattern 20 is formed of A6063 defined by Japanese Industrial Standards (JIS), for example.

The insulating substrate 30 is provided above the first circuit pattern 20 via the intermediate member 60. The insulating substrate 30 is formed of ceramic, for example. Ceramic is SIN, for example.

The second circuit pattern 40 is provided above the insulating substrate 30 via the intermediate member 60. The second circuit pattern 40 is formed of Al, for example. A degree of purity of Al is equal to or larger than 99.99 % (4N), for example.

The third circuit pattern 50 is provided above the second circuit pattern 40 via the intermediate member 60. The third circuit pattern 50 is formed of Al—Mg—Si alloy, for example. The third circuit pattern 50 is formed of A6063 defined by JIS, for example.

The intermediate members 60 are provided between the cooling fin 10 and the first circuit pattern 20, between the first circuit pattern 20 and the insulating substrate 30, between the insulating substrate 30 and the second circuit pattern 40, and between the second circuit pattern 40 and the third circuit pattern 50, respectively, as described above. A thickness of each intermediate member 60 is preferably smaller than that of any of the first circuit pattern 20, the second circuit pattern 40, and the third circuit pattern 50. The intermediate member 60 has conductivity, for example. The intermediate member 60 is a brazing sheet as a clad member in which a brazing material is rolled on a core material to be integrated with each other.

The semiconductor element is mounted on the third circuit pattern 50 via a bonding material (not shown), for example. The semiconductor element is also referred to as a semiconductor chip. The semiconductor element is formed of semiconductor such as Si, for example. The semiconductor element is preferably formed of a so-called wide bandgap semiconductor such as SiC, GaN, Ga₂O₃, and diamond, for example. The semiconductor element is a power semiconductor element or a control integrated circuit (IC) for controlling the power semiconductor element. The semiconductor element includes an insulated gate bipolar transistor (IGBT), a metal oxide semiconductor field effect transistor (MOSFET), or a Schottky barrier diode, for example. The semiconductor element may include a reverse-conducting IGBT (RC-IGBT) in which an IGBT and a reflux diode are formed in one semiconductor substrate.

A thickness of the first circuit pattern 20 is smaller than that of at least one of the second circuit pattern 40 and the third circuit pattern 50. The first circuit pattern 20 preferably has a thickness such that a difference between a volume of a member above the insulating substrate 30 and a volume of a member below the insulating substrate 30 is within 15%. Herein, the member below the insulating substrate 30 includes only the plate part 10A dominantly relating to rigidity of the cooling fin 10 in the cooling fin 10. The plate part 10A dominantly relating to rigidity of the cooling fin 10 corresponds to a region A shown by an oblique line in FIG. 2 In other words, the member below the insulating substrate 30 described above does not include a frame part provided to an outer surrounding of the fin part 10B and the plate part 10A of the cooling fin 10.

In such a semiconductor device 101, rigidity of the member below the insulating substrate 30 is reduced. Thus, a warpage after the power module substrate and the cooling fin 10 are bonded is reduced. For example, a warpage convexed to a side of the cooling fin 10, that is to say, a lower side is reduced.

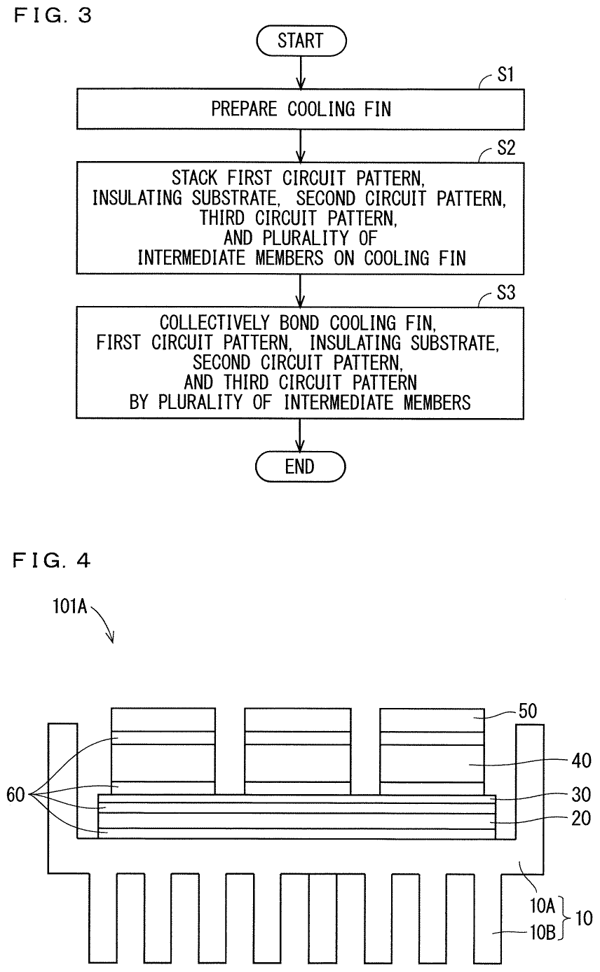

FIG. 3 is a flow chart illustrating a method of manufacturing the semiconductor device 101 according to the embodiment 1.

In Step S1, the cooling fin 10 is prepared.

In Step S2, the first circuit pattern 20, the insulating substrate 30, the second circuit pattern 40, the third circuit pattern 50, and the plurality of intermediate members 60 are stacked on the cooling fin 10. At this time, the intermediate members 60 are provided between the cooling fin 10 and the first circuit pattern 20, between the first circuit pattern 20 and the insulating substrate 30, between the insulating substrate 30 and the second circuit pattern 40, and between the second circuit pattern 40 and the third circuit pattern 50, respectively. A thickness of the first circuit pattern 20 is smaller than that of at least one of the second circuit pattern 40 and the third circuit pattern 50.

In Step S3, the cooling fin 10, the first circuit pattern 20, the insulating substrate 30, the second circuit pattern 40, and the third circuit pattern 50 are collectively bonded to each other by the plurality of intermediate members 60.

The semiconductor element is mounted on the third circuit pattern 50 after Step S3, for example. The semiconductor device 101 according to the embodiment 1 is thereby completed.

In such a manufacturing method, after each member is stacked on the cooling fin 10, each member is bonded collectively by the intermediate member 60. Favorite bond properties are achieved even in a case where a thickness of a circuit pattern above the insulating substrate 30 and a thickness of a circuit pattern below the insulating substrate 30 are different from each other.

To sum up the above, the semiconductor device 101 according to the embodiment 1 includes the cooling fin 10, the first circuit pattern 20, the insulating substrate 30, the second circuit pattern 40, the third circuit pattern 50, and the plurality of intermediate members 60. The first circuit pattern 20 is attached to the cooling fin 10. The insulating substrate 30 is provided above the first circuit pattern 20. The second circuit pattern 40 is provided above the insulating substrate 30. The third circuit pattern 50 is provided above the second circuit pattern 40. The plurality of intermediate members 60 are provided between the cooling fin 10 and the first circuit pattern 20, between the first circuit pattern 20 and the insulating substrate 30, between the insulating substrate 30 and the second circuit pattern 40, and between the second circuit pattern 40 and the third circuit pattern 50, respectively. A thickness of the first circuit pattern 20 is smaller than that of at least one of the second circuit pattern 40 and the third circuit pattern 50.

In such a semiconductor device 101, a warpage after the power module substrate and the cooling fin 10 are bonded is reduced.

### Modification Example 1 of Embodiment 1

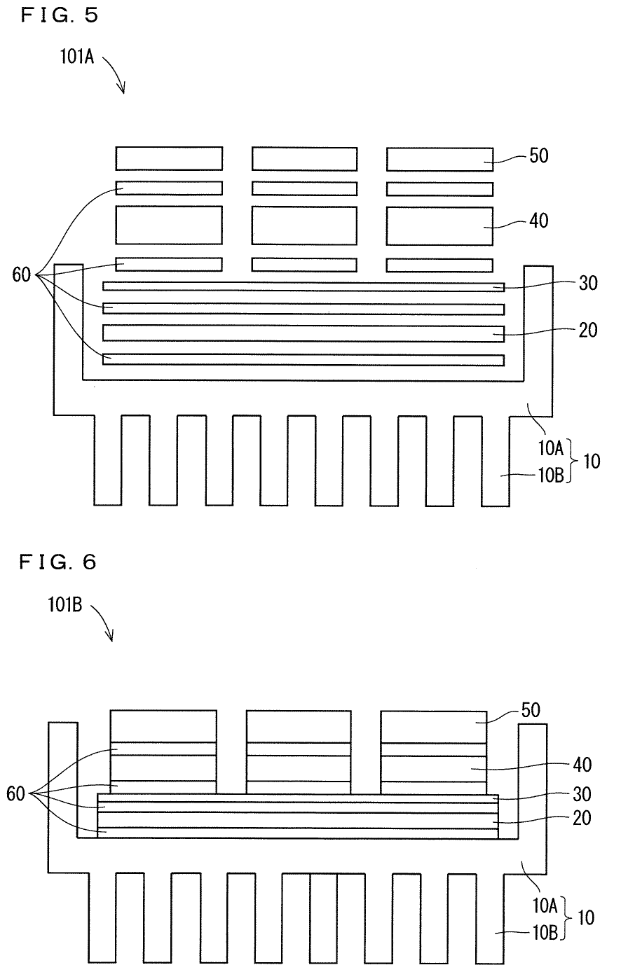

FIG. 4 is a cross-sectional view illustrating a configuration of a semiconductor device 101A according to a modification example 1 of the embodiment 1. FIG. 5 is a cross-sectional view illustrating a configuration of a member included in the semiconductor device 101A.

The second circuit pattern 40 according to the modification example 1 has a larger thickness than the third circuit pattern 50. A thickness of the first circuit pattern 20 is smaller than that of at least one of the second circuit pattern 40 and the third circuit pattern 50. Also according to such a configuration, an effect similar to that in the embodiment 1 is obtained.

### Modification Example 2 of Embodiment 1

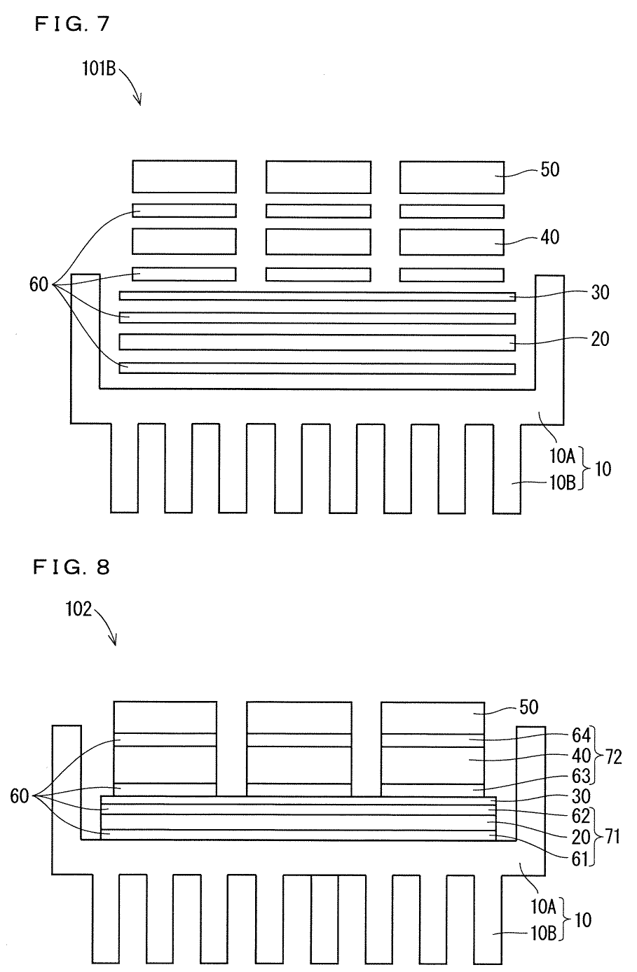

FIG. 6 is a cross-sectional view illustrating a configuration of a semiconductor device 101B according to a modification example 2 of the embodiment 1. FIG. 7 is a cross-sectional view illustrating a configuration of a member included in the semiconductor device 101B.

The third circuit pattern 50 according to the modification example 2 has a larger thickness than the second circuit pattern 40. A thickness of the first circuit pattern 20 is smaller than that of at least one of the second circuit pattern 40 and the third circuit pattern 50. Also according to such a configuration, an effect similar to that in the embodiment 1 is obtained.

### Embodiment 2

In an embodiment 2, the same reference numerals are assigned to constituent elements similar to those in the embodiment 1, and the detailed description thereof is omitted.

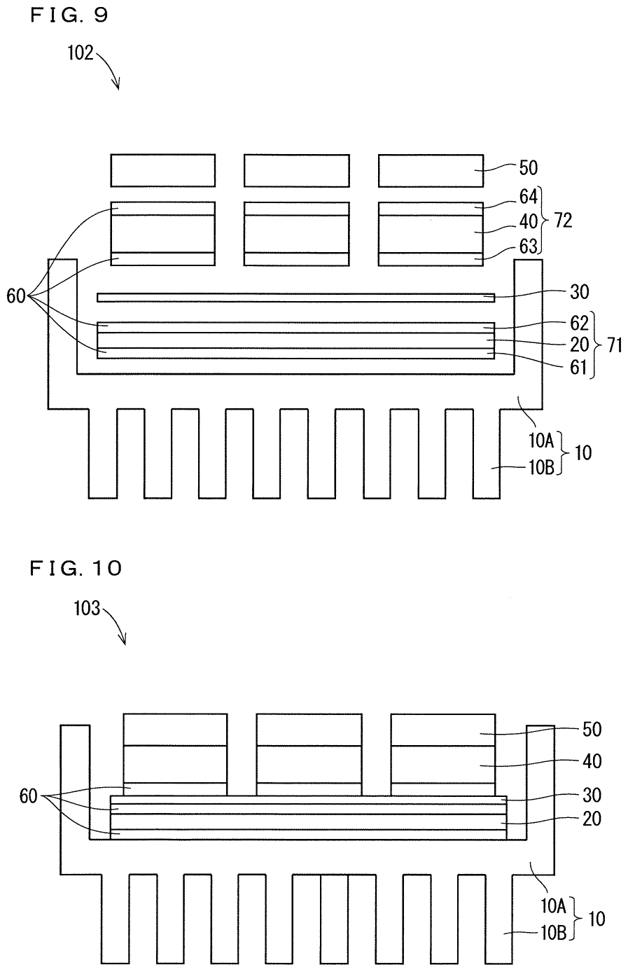

FIG. 8 is a cross-sectional view illustrating a configuration of a semiconductor device 102 according to the embodiment 2. FIG. 9 is a cross-sectional view illustrating a configuration of a member included in the semiconductor device 102.

The semiconductor device 102 includes a first clad member 71 and a second clad member 72. The plurality of intermediate members 60 include a first intermediate member 61, a second intermediate member 62, a third intermediate member 63, and a fourth intermediate member 64.

The first clad member 71 includes the first circuit pattern 20, the first intermediate member 61, and the second intermediate member 62. The first circuit pattern 20 is a base member. The first intermediate member 61 is bonded to a lower surface of the first circuit pattern 20 as a brazing material. The second intermediate member 62 is bonded to an upper surface of the first circuit pattern 20 as a brazing material. The first clad member 71 is a double-sided brazing material clad circuit pattern in which a brazing material is bonded to both surfaces of the first circuit pattern 20.

The second clad member 72 includes the second circuit pattern 40, the third intermediate member 63, and the fourth intermediate member 64. The second circuit pattern 40 is a base member. The third intermediate member 63 is bonded to a lower surface of the second circuit pattern 40 as a brazing material. The fourth intermediate member 64 is bonded to the upper surface of the second circuit pattern 40 as a brazing material. The second clad member 72 is a double-sided brazing material clad circuit pattern in which a brazing material is bonded to both surfaces of the second circuit pattern 40. In the manufacturing method, each member in FIG. 9 is stacked in Step S2 in FIG. 3, and is collectively bonded in Step S3.

Also according to such a configuration, an effect similar to that in the embodiment 1 is obtained. Furthermore, the number of components constating the semiconductor device 102 is reduced, and heat resistance is reduced.

### Embodiment 3

In an embodiment 3, the same reference numerals are assigned to constituent elements similar to those in the embodiment 1 or 2, and the detailed description thereof is omitted.

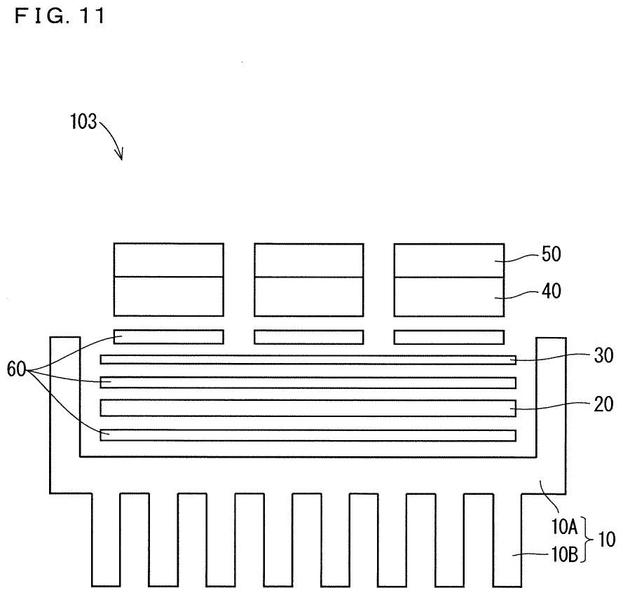

FIG. 10 is a cross-sectional view illustrating a configuration of a semiconductor device 103 according to the embodiment 3. FIG. 11 is a cross-sectional view illustrating a configuration of a member included in the semiconductor device 103.

The second circuit pattern 40 and the third circuit pattern 50 are clad members directly bonded to each other. The second circuit pattern 40 is formed of Al, for example. A degree of purity of Al is equal to or larger than 99.99 % (4N), for example. The third circuit pattern 50 is formed of Cu, for example. A thickness of the first circuit pattern 20 is smaller than that of at least one of the second circuit pattern 40 and the third circuit pattern 50. In the manufacturing method, each member in FIG. 11 is stacked in Step S2 in FIG. 3, and is collectively bonded in Step S3.

Also according to such a configuration, an effect similar to that in the embodiment 1 is obtained. Furthermore, the number of components constating the semiconductor device 103 is reduced, and heat resistance is reduced.

Although the present disclosure is described above in detail, the foregoing description is in all aspects illustrative and does not restrict the disclosure. It is therefore understood that numerous modification examples not exemplified can be devised.

In the present disclosure, each embodiment can be arbitrarily combined, or each embodiment can be appropriately varied or omitted.

### EXPLANATION OF REFERENCE SIGNS

10 cooling fin, 10A plate part, 10B fin part, 20 first circuit pattern, 30 insulating substrate, 40 second circuit pattern, 50 third circuit pattern, 60 intermediate member, 61 first intermediate member, 62 second intermediate member, 63 third intermediate member, 64 fourth intermediate member, 71 first clad member, 72 second clad member, 101 semiconductor device, 101A semiconductor device, 101B semiconductor device, 102 semiconductor device, 103 semiconductor device, A region.

1. A semiconductor device, comprising:
a cooling fin;
a first circuit pattern attached to the cooling fin;
an insulating substrate provided above the first circuit pattern;
a second circuit pattern provided above the insulating substrate;
a third circuit pattern provided above the second circuit pattern; and
a plurality of intermediate members provided between the cooling fin and the first circuit pattern, between the first circuit pattern and the insulating substrate, between the insulating substrate and the second circuit pattern, and between the second circuit pattern and the third circuit pattern, respectively, wherein
a thickness of the first circuit pattern is smaller than a thickness of at least one of the second circuit pattern and the third circuit pattern.

2. The semiconductor device according to claim 1, wherein
the second circuit pattern has a larger thickness than the third circuit pattern.

3. The semiconductor device according to claim 1, wherein
the third circuit pattern has a larger thickness than the second circuit pattern.

4. The semiconductor device according to claim 1, further comprising:
a first clad member; and
a second clad member, wherein
the plurality of intermediate members include:
a first intermediate member bonded to a lower surface of the first circuit pattern as a brazing material;
a second intermediate member bonded to an upper surface of the first circuit pattern as a brazing material;
a third intermediate member bonded to a lower surface of the second circuit pattern as a brazing material; and
a fourth intermediate member bonded to an upper surface of the second circuit pattern as a brazing material,
the first clad member includes the first circuit pattern, the first intermediate member, and the second intermediate member, and
the second clad member includes the second circuit pattern, the third intermediate member, and the fourth intermediate member.

5. A semiconductor device, comprising:
a cooling fin;
a first circuit pattern attached to the cooling fin;
an insulating substrate provided above the first circuit pattern;
a second circuit pattern provided above the insulating substrate;
a third circuit pattern provided above the second circuit pattern; and
a plurality of intermediate members provided between the cooling fin and the first circuit pattern, between the first circuit pattern and the insulating substrate, and between the insulating substrate and the second circuit pattern, wherein
a thickness of the first circuit pattern is smaller than a thickness of at least one of the second circuit pattern and the third circuit pattern, and
the second circuit pattern and the third circuit pattern are clad members directly bonded to each other.

6. A method of manufacturing a semiconductor device, comprising:
preparing a cooling fin;
stacking a first circuit pattern, an insulating substrate, a second circuit pattern, a third circuit pattern, and a plurality of intermediate members on the cooling fin; and
collectively boding the cooling fin, the first circuit pattern, the insulating substrate, the second circuit pattern, and the third circuit pattern by the plurality of intermediate members, wherein
the plurality of intermediate members are provided between the cooling fin and the first circuit pattern, between the first circuit pattern and the insulating substrate, between the insulating substrate and the second circuit pattern, and between the second circuit pattern and the third circuit pattern, respectively, and
a thickness of the first circuit pattern is smaller than a thickness of at least one of the second circuit pattern and the third circuit pattern.
